(19) United States
(12) Patent Application Publication
(10) Pub. No.: US 2023/0209712 A1
(43) Pub. Date: Jun. 29, 2023

(54) DOUBLE-SIDED PLASTIC PACKAGE POWER SUPPLY PRODUCT

(71) Applicant: MORNSUN GUANGZHOU SCIENCE & TECHNOLOGY CO., LTD., Guangdong (CN)

(72) Inventors: Youyuan TAN, Guangdong (CN); Zhifang YU, Guangdong (CN); Wenjie LIANG, Guangdong (CN)

(73) Assignee: MORNSUN GUANGZHOU SCIENCE & TECHNOLOGY CO., LTD., Guangdong (CN)

(21) Appl. No.: 17/911,425

(22) PCT Filed: Dec. 29, 2021
(86) PCT No.: PCT/CN2021/142351

§ 371 Date: Sep. 14, 2022

(30) Foreign Application Priority Data
Dec. 31, 2020 (CN) 202011632549.4

(51) Int. Cl. H05K 1/11

(52) U.S. Cl. CPC H05K 1/117; H05K 2201/1034; H05K 2201/09445

(57) ABSTRACT

Provided is a double-sided plastic package power supply product, including a PCB, a plastic package body, electric contacts and pins, wherein the electric contact is connected to the pin and the PCB; the pin includes a plastic body and a metal body; the metal body is embedded in the plastic body; the plastic body is used to limit the metal body; and one end of the metal body is connected to the electric contact, and the other end of the metal body is used as a plug pin. A metal terminal is connected to a PCB substrate and wrapped in the plastic package body, and the surface of the portions of the metal terminal that protrude from the PCB substrate can be exposed on the surface of the product by means of cutting or thinning so as to form the electric contacts.

### BACKGROUND

### Technical Field

The disclosure relates to the field of plastic package power supplies, in particular to a double-sided plastic package power supply product.

### Description of Related Art

The existing double-sided plastic package products are products with PCB as substrate and metal frame as substrate. For products with a metal frame as the substrate, the product pins are led out from the lateral side of the product through the metal frame. This type of solution uses lead frame for welding products. Generally, only one layer of wiring is available, and it is not possible to perform multi-layer wiring like a PCB. With the same number of components, the product area is relatively big.

For products with PCB as the substrate, a part of the PCB of the product is generally reserved for non-plastic packaging, which is used as a product pin terminal or connected with a pin. This type of solution requires selective plastic package molds, which have poor compatibility with product size, and the selective plastic package molds is generally more expensive than that of integral one-time plastic package molds.

Another solution for products using PCB as substrate is to use the copper layer inside the PCB as electrical contacts for assembling and welding with external pins. However, the area of the copper layer exposed after cutting is small, which will have a greater negative impact on thermal conductivity of the product.

### SUMMARY

In order to overcome the above-mentioned defects of the related art, the present disclosure provides a double-sided plastic package power supply product. The double-sided plastic package power supply product may adopt an integral plastic package mold for double-sided plastic packaging, so that dependence on the mold may be reduced from product design and size compatibility of the mold on the product may be increased.

In order to achieve the above purpose, the technical scheme adopted in the present disclosure is:

A double-sided plastic package power supply product includes a PCB board, a plastic package body, electrical contacts and pins. The electrical contacts connect the pins and the PCB board. The disclosure is characterized in that the pins include a plastic body and a metal body, and the metal body is embedded in the plastic body. The plastic body is used to limit the position of the metal body, one end of the metal body is connected to the electrical contact, and the other end of the metal body is used as a plug pin. Preferably, on the plastic body, a surface in contact with the plastic package body is provided with a groove for applying adhesive to reinforce the pin connection.

Preferably, the double-sided plastic package power supply product further includes metal terminals. The metal terminals are connected to the PCB board, the metal terminals are arranged at the border of the PCB board, with the outer side protruding from the cutting line of the PCB board. The upper and lower surfaces of the PCB board on which the metal terminals are mounted are integrally plastic package, and the electrical contacts are formed by the new outer surfaces of the metal terminals exposed by cutting or thinning.

Preferably, a metal terminal is further included. The metal terminal is wrapped by the plastic package body. The metal terminal is arranged at the border of the PCB board and is connected to the PCB board, and one end of the metal terminal is provided with the electrical contacts, and the electrical contacts of the metal terminals are exposed on the surface of the double-sided plastic package power supply.

Preferably, one end of the metal terminal is cut to form the electrical contact; the length and width of the plastic package body are consistent with the length and width of the PCB board.

Preferably, the metal terminals are connected to the PCB board through plug-in welding or patch welding.

Preferably, a metal blind hole or a metal through hole is opened on the lateral side of the PCB board, the hole wall of the metal blind hole or metal through hole is made of metal, and the metal blind hole or metal through hole is arranged along the cutting line of the double-sided plastic package power supply product. The electrical contact is formed by cutting the hole wall of the metal blind hole or the metal through hole along the cutting line.

Preferably, the electrical contacts are in the shape of a concave arc.

Preferably, a metal blind hole or a through hole is opened at the border of the PCB board, the metal blind hole or through hole is arranged along the cutting line of the PCB board, and the metal blind hole or the through hole is filled with weak adhesive which is easy to remove after the product is cut. The upper and lower surfaces of the PCB board are integrally plastic package, and the electrical contacts are formed by cutting a concave arc shape exposed on the lateral surface of the PCB board.

Preferably, the processing of the hole wall of the metal blind hole is the same as the processing of the bonding pad on the surface of the PCB board.

Preferably, electronic components are further included. The electronic components are connected to the PCB board through the bonding pads on the surface of the PCB board, and are wrapped in the plastic package body or exposed on the surface of the plastic package body.

Preferably, the pins are welded together with the electrical contacts by through-hole soldering, conductive adhesive or metal fusion welding to form an electrical connection with the PCB board.

Preferably, the pins can withstand a reflow temperature of 260° C.

By using the above solution, when the length and width of the plastic package body is the same as the length and width of the PCB board, the electrical contacts may be drawn from the surface of the product, and then the structural members serving as pins are used to form electrical connections with the electrical contacts and bonded to the lateral side of the product, thereby completing the production of such double-sided plastic package product.

The following advantageous effects may be achieved:

1. The integral plastic package mold may be used as a double-sided plastic package product, so that dependence on the mold may be reduced from product design and size compatibility of the mold on the product may be increased.

2. One solution is to use metal terminals as electrical contacts for assembling and welding with the pins. The thermal conductivity of metal terminals is high, which facilitates heat dissipation for product.

3. One solution is to use the via holes of the PCB as electrical contacts through processing. After cutting, the solderable coating of the hole wall is not damaged, which facilitates the welding of the hole wall and the pins in the process. In the meantime, the hole wall is utilized without occupying the space on the surface of PCB, so that the layout space of the PCB surface may be increased.

### BRIEF DESCRIPTION OF THE DRAWINGS

FIG. 1 is a cross-sectional view of a first embodiment of the present disclosure.

FIG. 2 is a perspective view of the first embodiment of the present disclosure.

FIG. 3 is a schematic structural view of a metal body according to the first embodiment of the present disclosure.

FIG. 4 is a schematic structural view of a pin according to the first embodiment of the present disclosure.

FIG. 5 is a diagram showing the cutting process of the first embodiment of the present disclosure.

FIG. 6 is a schematic view after the cutting process of the first embodiment of the present disclosure.

FIG. 7 is a schematic view of the first embodiment of the present disclosure.

FIG. 8 is a cross-sectional view of a second embodiment of the present disclosure.

FIG. 9 is a schematic structural view of a metal body according to the second embodiment of the present disclosure.

FIG. 10 is a schematic structural view of a pin of the second embodiment of the present disclosure.

FIG. 11 is a schematic view after the cutting process of the second embodiment of the present disclosure.

FIG. 12 is another schematic view after the cutting process of the second embodiment of the present disclosure.

FIG. 13 is a schematic view of the second embodiment of the present disclosure.

### DESCRIPTION OF THE EMBODIMENTS

The technical solutions of the present disclosure will be described in detail below in conjunction with the accompanying drawings.

### First Embodiment

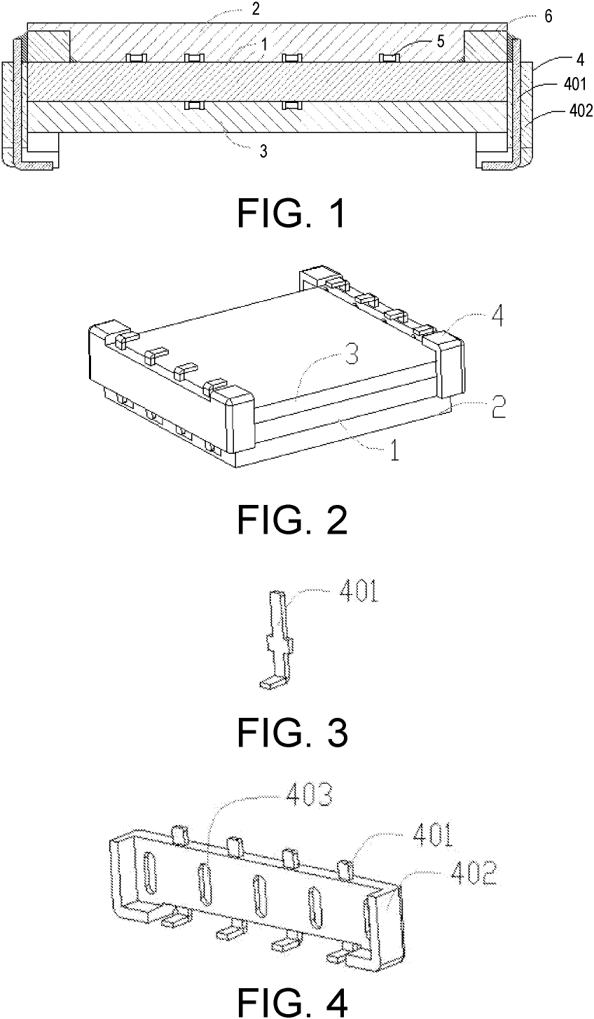

As shown in FIG. 2, the double-sided plastic package power supply product of the present disclosure includes a PCB board 1, a first plastic package body 2, a second plastic package body 3, a pin 4, an electronic component 5 welded on the PCB, and a metal terminal 6. As shown in FIG. 1, the pin 4 includes a plastic body 402 and a metal body 401. The length and width of the first plastic package body 2 and the second plastic package body 3 are consistent with the length and width of the PCB board 1. The metal terminal 6 of the product is arranged on one side of the PCB board 1. The metal terminal 6 is arranged at the border of the product, and arranged along the cutting line of the double-sided plastic package power supply product.

As shown in FIG. 3, the metal body 401 includes a transverse portion serving as a plug pin and a vertical portion for connecting an electrical contact of the metal terminal 6. As shown in FIG. 4, the plastic body 402 serves to fix the metal body 401. In order to ensure the assembly strength of the pin 4 of product and the overall double-sided plastic package power supply, in addition to welding the metal body 401 of the pin 4 and the metal terminal 6 of the product, an adhesive may be added for fixing, and a corresponding groove 403 may be opened on the plastic body 402 for applying adhesive. The position where the adhesive is applied needs to be set away from the welding position of the pin 4 and the metal terminal 6.

Since the pin 4 of product is assembled on two sides of the product, it is necessary to ensure the flatness and pin shift of the pin 4 of product after the pin 4 is assembled. One solution is to make a corresponding position-limiting design on the plastic body of the pin 4. When assembling the pin 4, the position-limiting structure is used to control the flatness of pin 4 and shift of the two rows of pins 4 after assembly of the pin 4 of product. One solution is that no position-limiting structure is designed on the plastic body of the pin 4. During assembly, the positions of pin 4 and the product are limited by a jig. Since the product is an SMD surface mount package product, and reflow soldering will be used later, the material of the plastic body 402 needs to be a high-temperature resistant material.

The fabrication of the double-sided plastic package power supply product in this embodiment includes the following steps:

Terminal patch step: A metal terminal 6 is provided, which is a square terminal, and the material thereof may be selected from copper or copper alloy. The metal terminal 6 is attached to the PCB board along the cutting line, and one end of the metal terminal 6 is beyond the cutting line.

Double-sided plastic packaging step: This product adopts a double-sided plastic package mold to form the first plastic package body 2 and the second plastic package body 3 through processing. The plastic package mold cavity of the double-sided plastic package mold can make multiple PCB boards, leaving a cutting lane between each PCB board. The width of the cutting lane is matched with the width of the corresponding cutting knife. Generally, the width of the cutting lane is slightly larger than the thickness of the cutting knife. The double-sided plastic package mold may have only one injection runner or two injection runners. When there is only one injection runner, it is necessary to open a slot penetrating through the PCB board 1 near the corresponding injection runner on the PCB board 1, so that the molding compound can fill both sides of the PCB board 1 during injection molding. When there are two injection runners, the two injection runners are arranged on both sides of the PCB board 1 respectively.

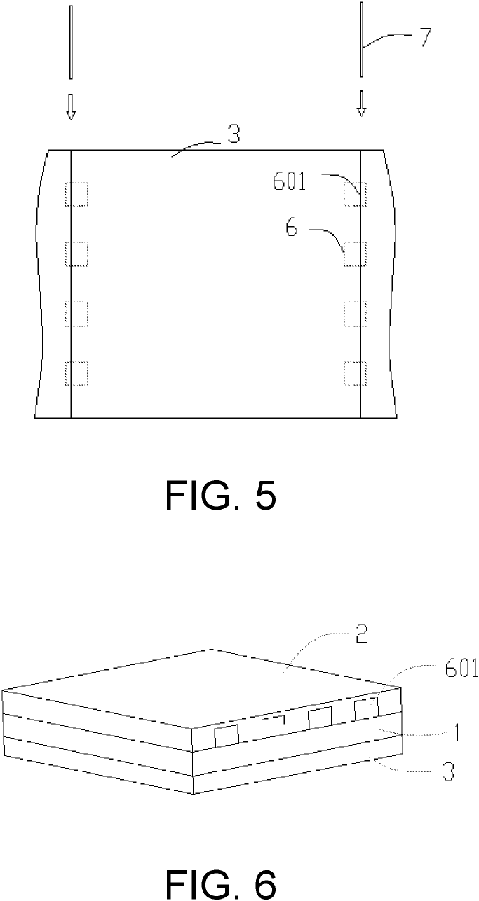

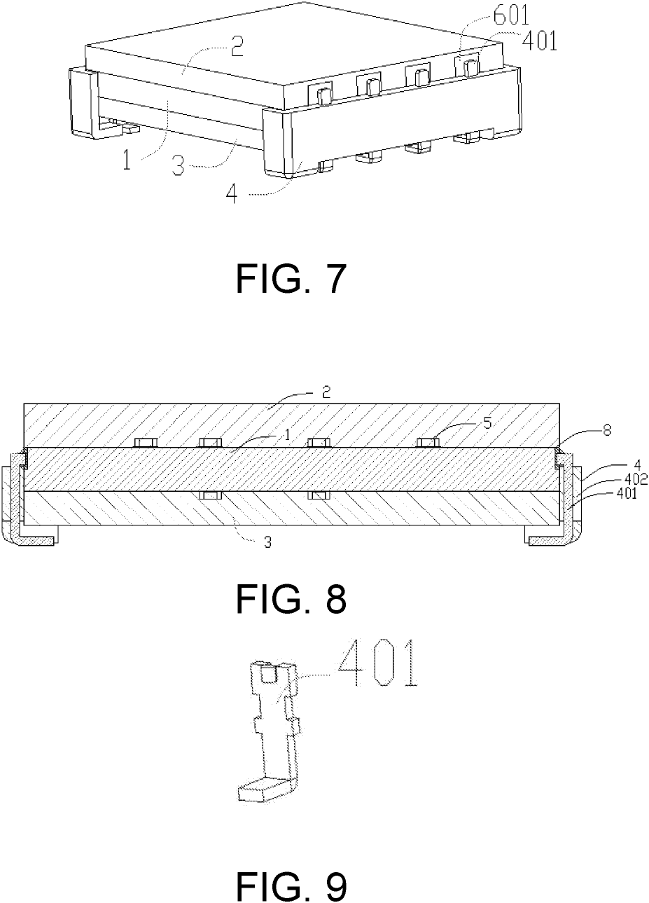

Cutting step: Referring to FIG. 5, the metal terminal 6, the first plastic package body 2, the PCB board 1, and the second plastic package body 3 are cut along the cutting line, and the part beyond the cutting line is removed. After cutting, the cut surface 601 of the metal terminal 6 exposes the lateral side of the plastic package body (the first plastic package body 2 or the second plastic package body 3). The cut surface 601 of the metal terminal 6 serves as an electrical contact electrically connected to the metal body 401.

Welding step: Referring to FIG. 6, the cut surface of the cut metal terminal 6 is easily oxidized, so it is necessary to assemble and weld the pin 4 of product before the cut surface of the metal terminal 6 is oxidized, or anti-oxidation treatment is performed in advance on the cut surface of the metal terminal 6, for example, by coating the cut surface with OSP molding agent, or electroplating the cut surface 601 of the metal terminal 6. The pin 4 may selectively expose the part where the pin 4 and metal terminal 6 are assembled and welded. Then, when the assembly and welding of the pin 4 and metal terminal 6 are performed, local heating may be used for welding, and only the electrical contact between the metal body 401 and metal terminal 6 is heated. Local heating methods include robotic welding, soldering iron welding, and laser local welding. It is also possible to choose to cover the part where the metal body 401 and the electrical contact are assembled and welded with a plastic body. In this case, the assembly and welding of the metal body 401 and the electrical contact of the metal terminal 6 is difficult to be performed by means of local heating. The overall product is subjected to heat soldering, such as reflow soldering. Such double-sided plastic package surface mount products are generally moisture-sensitive devices, and the number of reflow soldering is strictly controlled. It is generally recommended to perform reflow soldering at most three times after plastic packaging. If one reflow soldering is used at this time, the number of reflow soldering that the customer can use will be correspondingly reduced by one.

### Second Embodiment

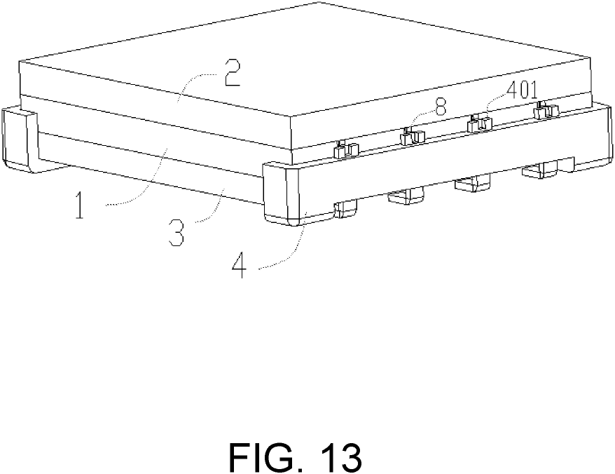

As shown in FIG. 8 to FIG. 13, the double-sided plastic package power supply product includes a PCB board 1, a first plastic package body 2, a second plastic package body 3, an electronic component 5 soldered on the PCB board 1, a pin 4 and a metal electrical contact 8. The length and width of the first plastic package body 2 and the second plastic package body 3 are consistent with the length and width of the PCB board 1. A metal blind hole is opened on the lateral side near the PCB board 1, which is exposed on the surface of the product after cutting to form the metal electrical contact 8. The pin 4 and the metal electrical contact 8 are welded by soldering to form an electrical connection. The pin 4 includes a plastic body 402 and a metal body 401. The plastic body 402 is provided with a groove 403, which is the adhesive applying position.

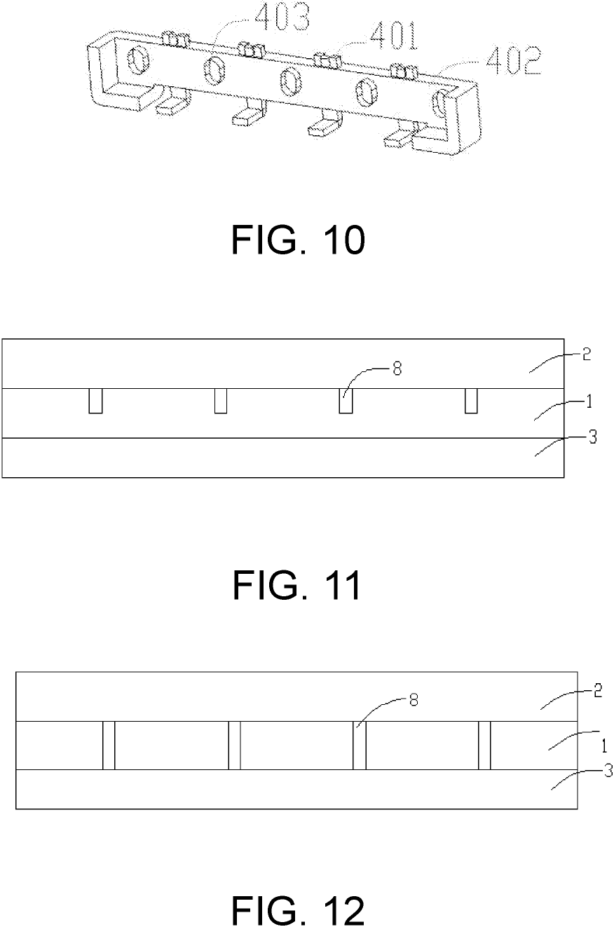

As shown in FIG. 9, FIG. 9 is a schematic structural view of the metal body 401, and as shown in FIG. 10, FIG. 10 is a structural view of the pin 4. Their structures and connection mode are similar to those of the first embodiment, and are not repeated here.

The connection method of the product of this embodiment is the same as that of the first embodiment, and the difference is that the formation process of the metal electrical contact 8 is different, and the details are as follows:

The metal electrical contact 8 is formed by cutting metal blind holes or through holes arranged at the border of the product, and the metal blind holes are arranged along the cutting line of the product. Before plastic packaging, it is necessary to fill the inside of the metal blind hole with a substance, which has weak adhesion to the metal hole wall. After the product is cut, this substance may be removed to expose the hole wall of the blind hole. A cross-sectional view of the product after removal of material is shown in FIG. 11 or FIG. 12. The choice of material may be an adhesive with weak adhesion to the metal or a special adhesive such as photoresist. The filling of such substances may be completed when the PCB board 1 manufacturer manufactures the PCB board 1, or may be filled by the manufacturer itself during processing.

The metal electrical contact 8 is in the shape of a concave arc on the lateral side of the PCB board 1. The hole wall treatment in the metal blind hole is the same as that of the bonding pad treatment on the surface of the PCB board 1, which is tin-plated or immersion gold or nickel-palladium-gold treatment. Therefore, after cutting, the hole wall may be welded and assembled with the pin 4 without any other processing. Since the metal electrical contact 8 is composed of blind holes, only a small part of the space on one side of the PCB board 1 is occupied, which increases the layout space occupied by the electronic component 5 on the PCB board 1. The aperture size of the blind hole needs to match the size of the corresponding welded part on the pin 4. When the blind hole is at the position of the cutting line and the distance inside the product is less than or equal to 0.2 mm, it is easier to take out the filling material from the hole after the product is cut. If the distance inside the product is greater than 0.2 mm, a “convex” structure design is made on the welding part of the pin 4 of product and the electrical contact to facilitate the assembly and welding of the pin 4 and the electrical contact.

The above are only the preferred embodiments of the present disclosure. It should be noted that the above preferred embodiments should not be regarded as limitations of the present disclosure. For those skilled in the art, without departing from the spirit and scope of the present disclosure, several improvements and modifications can be made, and these improvements and modifications should also be regarded as the protection scope of the present disclosure, and the protection scope of the present disclosure should be subject to the scope defined by the claims.

1. A double-sided plastic package power supply product, comprising: a PCB board, a plastic package body, an electrical contact and a pin, wherein the electrical contact connects the pin and the PCB board, and the pin comprises a plastic body and a metal body, and the metal body is embedded in the plastic body, the plastic body is configured to limit a position of the metal body, one end of the metal body is connected to the electrical contact, and the other end of the metal body is used as the pin.

2. The double-sided plastic package power supply product according to claim 1, wherein on the plastic body, a surface in contact with the plastic package body is provided with a groove for applying an adhesive to strengthen connection of the pin.

3. The double-sided plastic package power supply product according to claim 1, further comprising a metal terminal, wherein the metal terminal is connected to the PCB board, the metal terminal is arranged at a border of the PCB board, with an outer side protruding from a cutting line of the PCB board, upper and lower surfaces of the PCB board on which the metal terminal is mounted are integrally plastic package, and the electrical contact is formed by a new outer surface of the metal terminal exposed by cutting or thinning.

4. The double-sided plastic package power supply product according to claim 1, further comprising a metal terminal, wherein the metal terminal is wrapped by the plastic package body, the metal terminal is arranged at a border of the PCB board and is connected to the PCB board, and one end of the metal terminal is provided with the electrical contact, and the electrical contact of the metal terminal is exposed on a surface of the double-sided plastic package power supply.

5. The double-sided plastic package power supply product according to claim 4, wherein the one end of the metal terminal is cut to form the electrical contact; a length and a width of the plastic package body are consistent with a length and a width of the PCB board.

6. The double-sided plastic package power supply product according to claim 4, wherein the metal terminal is connected to the PCB board through plug-in welding or patch welding.

7. The double-sided plastic package power supply product according to claim 1, wherein a metal blind hole or a metal through hole is opened on a lateral side of the PCB board, a hole wall of the metal blind hole or the metal through hole is made of metal, and the metal blind hole or the metal through hole is arranged along a cutting line of the double-sided plastic package power supply product, the electrical contact is formed by cutting the hole wall of the metal blind hole or the metal through hole along the cutting line.

8. The double-sided plastic package power supply product according to claim 7, wherein the electrical contact is in a shape of a concave arc.

9. The double-sided plastic package power supply product according to claim 1, wherein a metal blind hole or a through hole is opened at a border of the PCB board, the metal blind hole or the through hole is arranged along a cutting line of the PCB board, and the metal blind hole or the through hole is filled with a weak adhesive which is easy to remove after the product is cut, upper and lower surfaces of the PCB board are integrally plastic package, and the electrical contact is formed by cutting a concave arc shape exposed on a lateral surface of the PCB board.

10. The double-sided plastic package power supply product according to claim 7, wherein a processing of the hole wall of the metal blind hole is the same as a processing of a bonding pad on a surface of the PCB board.

11. The double-sided plastic package power supply product according to claim 1, further comprising an electronic component, wherein the electronic component is connected to the PCB board through a bonding pad on a surface of the PCB board, and is wrapped in the plastic package body or exposed on a surface of the plastic package body.

12. The double-sided plastic package power supply product according to claim 1, wherein the pin is welded together with the electrical contact by through-hole soldering, conductive adhesive or metal fusion welding to form an electrical connection with the PCB board.

13. The double-sided plastic package power supply product according to claim 1, wherein the pin is able to withstand a reflow temperature of 260° C.
